(19) United States
(12) Patent Application Publication
(10) Pub. No.: US 2017/0147219 A1
(43) Pub. Date: May 25, 2017

(54) UTILIZATION OF SOLID-STATE MEMORY DEVICES IN A DISPERSED STORAGE NETWORK

(71) Applicant: International Business Machines Corporation, Armonk, NY (US)

(72) Inventors: Wesley B. Leggette, Chicago, IL (US); Timothy W. Markison, Mesa, AZ (US); Jason K. Resch, Chicago, IL (US)

(21) Appl. No.: 15/427,408

(22) Filed: Feb. 8, 2017

Related U.S. Application Data
(63) Continuation-in-part of application No. 13/779,469, filed on Feb. 27, 2013.
Application No. 13/779,469 is a continuation of application No. 12/778,680, filed on May 12, 2010, now Pat. No. 8,478,937.
(60) Provisional application No. 61/247,190, filed on Sep. 30, 2009.

(51) Int. Cl. G06F 3/06; G06F 11/10

(52) U.S. Cl. CPC G06F 3/0604; G06F 3/0619; G06F 3/0634; G06F 3/064; G06F 3/0644; G06F 3/067; G06F 3/0679; G06F 11/1076; H03M 13/1515

(57) ABSTRACT

Methods for use in a dispersed storage network (DSN) to select memory devices for storage of encoded data, the memory devices including solid-state memory devices and at least one other type of memory devices. In various examples, a processing module receives a data object for storage in storage units of the DSN. The processing module determines metadata associated with the data object, and encodes the data object into encoded data slices. Based on the metadata (e.g., a data type, frequency of data access, data priority, performance indicator, etc.), the processing module selects a first storage mode of a plurality of storage modes for storage of at least one of the encoded data slices, wherein the first storage mode includes storage of the at least one of the encoded data in a storage unit utilizing solid-state memory devices. A current storage mode may be reassessed periodically or following a trigger event.

### CROSS-REFERENCE TO RELATED APPLICATIONS

The present U.S. Utility Patent Application claims priority pursuant to 35 U.S.C. §120 as a continuation-in-part of U.S. Utility application Ser. No. 13/779,469, entitled “METHOD AND APPARATUS FOR DISPERSED STORAGE MEMORY DEVICE UTILIZATION,” filed Feb. 27, 2013, which is a continuation of U.S. Utility application Ser. No. 12/778,680, entitled “METHOD AND APPARATUS FOR DISPERSED STORAGE MEMORY DEVICE UTILIZATION,” filed May 12, 2010 and now issued as U.S. Pat. No. 8,478,937, which claims priority pursuant to 35 U.S.C. §119(e) to U.S. Provisional Application No. 61/247,190, entitled “DISTRIBUTED STORAGE NETWORK MEMORY UTILIZATION,” filed Sep. 30, 2009, all of which are hereby incorporated herein by reference in their entirety and made part of the present U.S. Utility Patent Application for all purposes.

### STATEMENT REGARDING FEDERALLY SPONSORED RESEARCH OR DEVELOPMENT

Not applicable.

### INCORPORATION-BY-REFERENCE OF MATERIAL SUBMITTED ON A COMPACT DISC

Not applicable.

### BACKGROUND OF THE INVENTION

Technical Field of the Invention

This invention relates generally to computer networks, and more particularly to selection and utilization of solid-state memory devices in a dispersed storage network.

Description of Related Art

Computing devices are known to communicate data, process data, and/or store data. Such computing devices range from wireless smart phones, laptops, tablets, personal computers (PC), work stations, and video game devices, to data centers that support millions of web searches, stock trades, or on-line purchases every day. In general, a computing device includes a central processing unit (CPU), a memory system, user input/output interfaces, peripheral device interfaces, and an interconnecting bus structure.

As is further known, a computer may effectively extend its CPU by using “cloud computing” to perform one or more computing functions (e.g., a service, an application, an algorithm, an arithmetic logic function, etc.) on behalf of the computer. Further, for large services, applications, and/or functions, cloud computing may be performed by multiple cloud computing resources in a distributed manner to improve the response time for completion of the service, application, and/or function. For example, Hadoop is an open source software framework that supports distributed applications enabling application execution by thousands of computers.

In addition to cloud computing, a computer may use “cloud storage” as part of its memory system. As is known, cloud storage enables a user, via its computer, to store files, applications, etc. on a remote storage system. The remote storage system may include a RAID (redundant array of independent disks) system and/or a dispersed storage system that uses an error correction scheme to encode data for storage.

In a RAID system, a RAID controller adds parity data to the original data before storing it across an array of disks. The parity data is calculated from the original data such that the failure of a single disk typically will not result in the loss of the original data. While RAID systems can address certain memory device failures, these systems may suffer from effectiveness, efficiency and security issues. For instance, as more disks are added to the array, the probability of a disk failure rises, which may increase maintenance costs. When a disk fails, for example, it needs to be manually replaced before another disk(s) fails and the data stored in the RAID system is lost. To reduce the risk of data loss, data on a RAID device is often copied to one or more other RAID devices. While this may reduce the possibility of data loss, it also raises security issues since multiple copies of data may be available, thereby increasing the chances of unauthorized access. In addition, co-location of some RAID devices may result in a risk of a complete data loss in the event of a natural disaster, fire, power surge/outage, etc.

### BRIEF DESCRIPTION OF THE SEVERAL VIEWS OF THE DRAWING(S)

FIG. 1 is a schematic block diagram of an embodiment of a dispersed or distributed storage network (DSN) in accordance with the present disclosure;

FIG. 2 is a schematic block diagram of an embodiment of a computing core in accordance with the present disclosure;

FIG. 3 is a schematic block diagram of an example of dispersed storage error encoding of data in accordance with the present disclosure;

FIG. 4 is a schematic block diagram of a generic example of an error encoding function in accordance with the present disclosure;

FIG. 5 is a schematic block diagram of a specific example of an error encoding function in accordance with the present disclosure;

FIG. 6 is a schematic block diagram of an example of slice naming information for an encoded data slice (EDS) in accordance with the present disclosure;

FIG. 7 is a schematic block diagram of an example of dispersed storage error decoding of data in accordance with the present disclosure;

FIG. 8 is a schematic block diagram of a generic example of an error decoding function in accordance with the present disclosure;

FIG. 9 is a schematic block diagram of another embodiment of a DSN in accordance with the present disclosure;

FIG. 10 is a logic diagram of an example of determining data distribution in accordance with the present disclosure;

FIG. 11 a logic diagram of another example of determining data distribution in accordance with the present disclosure;

FIG. 12 is a schematic block diagram of an embodiment of a distributed storage unit in accordance with the present disclosure;

FIG. 13 is a logic diagram of another example of determining data distribution in accordance with the present disclosure; and

FIG. 14 is a logic diagram illustrating an example of memory device management in accordance with the present disclosure.

### DETAILED DESCRIPTION OF THE INVENTION

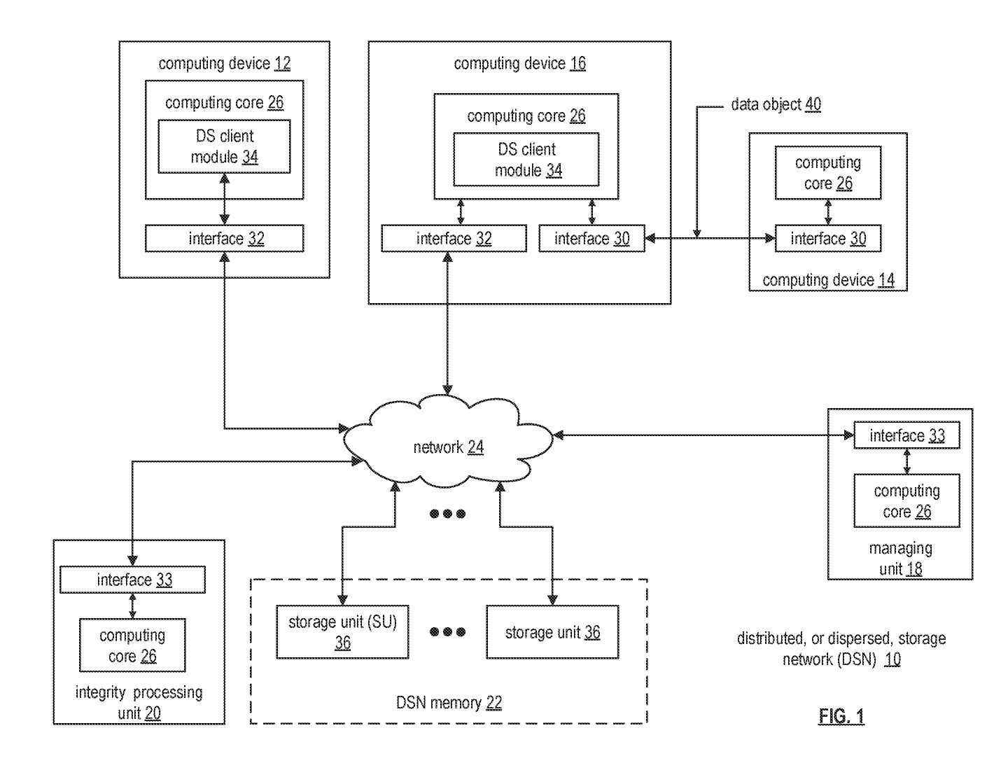

FIG. 1 is a schematic block diagram of an embodiment of a dispersed, or distributed, storage network (DSN) 10 that includes a plurality of computing devices 12-16, a managing unit 18, an integrity processing unit 20, and a DSN memory 22. The components of the DSN 10 are coupled to a network 24, which may include one or more wireless and/or wire lined communication systems; one or more non-public intranet systems and/or public internet systems; and/or one or more local area networks (LAN) and/or wide area networks (WAN).

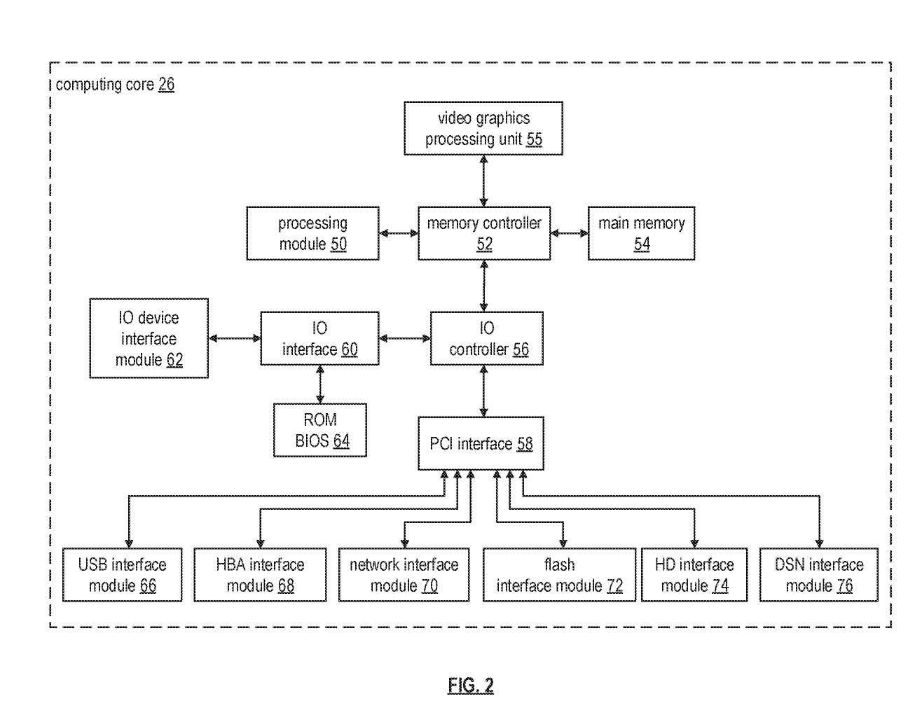

The DSN memory 22 includes a plurality of storage units 36 that may be located at geographically different sites (e.g., one in Chicago, one in Milwaukee, etc.), at a common site, or a combination thereof. For example, if the DSN memory 22 includes eight storage units 36, each storage unit is located at a different site. As another example, if the DSN memory 22 includes eight storage units 36, all eight storage units are located at the same site. As yet another example, if the DSN memory 22 includes eight storage units 36, a first pair of storage units are at a first common site, a second pair of storage units are at a second common site, a third pair of storage units are at a third common site, and a fourth pair of storage units are at a fourth common site. Note that a DSN memory 22 may include more or less than eight storage units 36. Further note that each storage unit 36 includes a computing core (as shown in FIG. 2, or components thereof) and a plurality of memory devices for storing dispersed storage (DS) error encoded data.

Each of the storage units 36 is operable to store DS error encoded data and/or to execute (e.g., in a distributed manner) maintenance tasks and/or data-related tasks. The tasks may be a simple function (e.g., a mathematical function, a logic function, an identify function, a find function, a search engine function, a replace function, etc.), a complex function (e.g., compression, human and/or computer language translation, text-to-voice conversion, voice-to-text conversion, etc.), multiple simple and/or complex functions, one or more algorithms, one or more applications, maintenance tasks (e.g., rebuilding and migration of data slices, updating hardware, rebooting software, restarting a particular software process, performing an upgrade, installing a software patch, loading a new software revision, performing an off-line test, prioritizing tasks associated with an online test, etc.), etc.

Each of the computing devices 12-16, the managing unit 18, integrity processing unit 20 and (in various embodiments) the storage units 36 include a computing core 26, which includes network interfaces 30-33. Computing devices 12-16 may each be a portable computing device and/or a fixed computing device. A portable computing device may be a social networking device, a gaming device, a cell phone, a smart phone, a digital assistant, a digital music player, a digital video player, a laptop computer, a handheld computer, a tablet, a video game controller, and/or any other portable device that includes a computing core. A fixed computing device may be a computer (PC), a computer server, a cable set-top box, a satellite receiver, a television set, a printer, a fax machine, home entertainment equipment, a video game console, and/or any type of home or office computing equipment. Note that each of the managing unit 18 and the integrity processing unit 20 may be separate computing devices, may be a common computing device, and/or may be integrated into one or more of the computing devices 12-16 and/or into one or more of the storage units 36.

Each interface 30, 32, and 33 includes software and hardware to support one or more communication links via the network 24 indirectly and/or directly. For example, interface 30 supports a communication link (e.g., wired, wireless, direct, via a LAN, via the network 24, etc.) between computing devices 14 and 16. As another example, interface 32 supports communication links (e.g., a wired connection, a wireless connection, a LAN connection, and/or any other type of connection to/from the network 24) between computing devices 12 and 16 and the DSN memory 22. As yet another example, interface 33 supports a communication link for each of the managing unit 18 and the integrity processing unit 20 to the network 24.

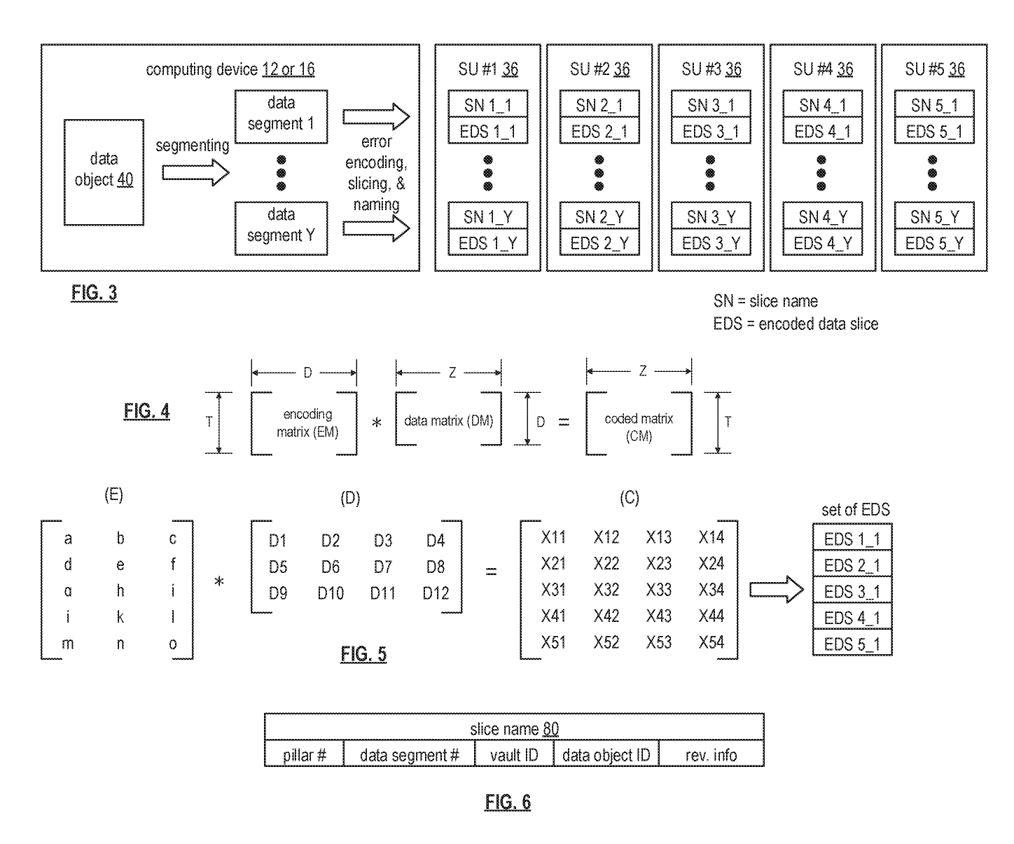

Computing devices 12 and 16 include a dispersed storage (DS) client module 34, which enables the computing device to dispersed storage error encode and decode data (e.g., data object 40) as subsequently described with reference to one or more of FIGS. 3-8. In this example embodiment, computing device 16 functions as a dispersed storage processing agent for computing device 14. In this role, computing device 16 dispersed storage error encodes and decodes data on behalf of computing device 14. With the use of dispersed storage error encoding and decoding, the DSN 10 is tolerant of a significant number of storage unit failures (the number of failures is based on parameters of the dispersed storage error encoding function) without loss of data and without the need for a redundant or backup copies of the data. Further, the DSN 10 stores data for an indefinite period of time without data loss and in a secure manner (e.g., the system is very resistant to unauthorized attempts at accessing the data).

In operation, the managing unit 18 performs DS management services. For example, the managing unit 18 establishes distributed data storage parameters (e.g., vault creation, distributed storage parameters, security parameters, billing information, user profile information, etc.) for computing devices 12-14 individually or as part of a group of user devices. As a specific example, the managing unit 18 coordinates creation of a vault (e.g., a virtual memory block associated with a portion of an overall namespace of the DSN) within the DSN memory 22 for a user device, a group of devices, or for public access and establishes per vault dispersed storage (DS) error encoding parameters for a vault. The managing unit 18 facilitates storage of DS error encoding parameters for each vault by updating registry information of the DSN 10, where the registry information may be stored in the DSN memory 22, a computing device 12-16, the managing unit 18, and/or the integrity processing unit 20.

The managing unit 18 creates and stores user profile information (e.g., an access control list (ACL)) in local memory and/or within memory of the DSN memory 22. The user profile information includes authentication information, permissions, and/or the security parameters. The security parameters may include encryption/decryption scheme, one or more encryption keys, key generation scheme, and/or data encoding/decoding scheme.

The managing unit 18 creates billing information for a particular user, a user group, a vault access, public vault access, etc. For instance, the managing unit 18 tracks the number of times a user accesses a non-public vault and/or public vaults, which can be used to generate per-access billing information. In another instance, the managing unit 18 tracks the amount of data stored and/or retrieved by a user device and/or a user group, which can be used to generate per-data-amount billing information.

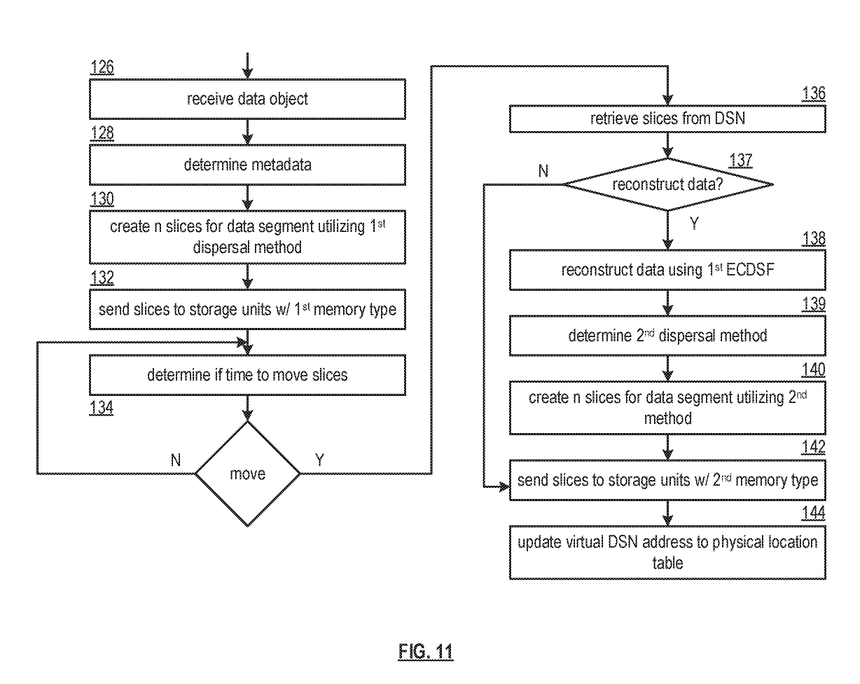

As another example, the managing unit 18 performs network operations, network administration, and/or network maintenance. Network operations includes authenticating user data allocation/access requests (e.g., read and/or write requests), managing creation of vaults, establishing authentication credentials for user devices, adding/deleting components (e.g., user devices, storage units, and/or computing devices with a DS client module 34) to/from the DSN 10, and/or establishing authentication credentials for the storage units 36. Network administration includes monitoring devices and/or units for failures, maintaining vault information, determining device and/or unit activation status, determining device and/or unit loading, and/or determining any other system level operation that affects the performance level of the DSN 10. Network maintenance includes facilitating replacing, upgrading, repairing, and/or expanding a device and/or unit of the DSN 10. Examples of load balancing, service differentiation and dynamic resource selection for data access operations are discussed in greater detail with reference to FIGS. 9-13.

To support data storage integrity verification within the DSN 10, the integrity processing unit 20 (and/or other devices in the DSN 10) may perform rebuilding of ‘bad’ or missing encoded data slices. At a high level, the integrity processing unit 20 performs rebuilding by periodically attempting to retrieve/list encoded data slices, and/or slice names of the encoded data slices, from the DSN memory 22. Retrieved encoded slices are checked for errors due to data corruption, outdated versioning, etc. If a slice includes an error, it is flagged as a ‘bad’ or ‘corrupt’ slice. Encoded data slices that are not received and/or not listed may be flagged as missing slices. Bad and/or missing slices may be subsequently rebuilt using other retrieved encoded data slices that are deemed to be good slices in order to produce rebuilt slices. A multi-stage decoding process may be employed in certain circumstances to recover data even when the number of valid encoded data slices of a set of encoded data slices is less than a relevant decode threshold number. The rebuilt slices may then be written to DSN memory 22. Note that the integrity processing unit 20 may be a separate unit as shown, included in DSN memory 22, included in the computing device 16, and/or distributed among the storage units 36.

FIG. 2 is a schematic block diagram of an embodiment of a computing core 26 that includes a processing module 50, a memory controller 52, main memory 54, a video graphics processing unit 55, an input/output (IO) controller 56, a peripheral component interconnect (PCI) interface 58, an IO interface module 60, at least one IO device interface module 62, a read only memory (ROM) basic input output system (BIOS) 64, and one or more memory interface modules. The one or more memory interface module(s) includes one or more of a universal serial bus (USB) interface module 66, a host bus adapter (HBA) interface module 68, a network interface module 70, a flash interface module 72, a hard drive interface module 74, and a DSN interface module 76.

The DSN interface module 76 functions to mimic a conventional operating system (OS) file system interface (e.g., network file system (NFS), flash file system (FFS), disk file system (DFS), file transfer protocol (FTP), web-based distributed authoring and versioning (WebDAV), etc.) and/or a block memory interface (e.g., small computer system interface (SCSI), internet small computer system interface (iSCSI), etc.). The DSN interface module 76 and/or the network interface module 70 may function as one or more of the interface 30-33 of FIG. 1. Note that the IO device interface module 62 and/or the memory interface modules 66-76 may be collectively or individually referred to as IO ports.

FIG. 3 is a schematic block diagram of an example of dispersed storage error encoding of data. When a computing device 12 or 16 has data to store it disperse storage error encodes the data in accordance with a dispersed storage error encoding process based on dispersed storage error encoding parameters. The dispersed storage error encoding parameters include an encoding function (e.g., information dispersal algorithm, Reed-Solomon, Cauchy Reed-Solomon, systematic encoding, non-systematic encoding, on-line codes, etc.), a data segmenting protocol (e.g., data segment size, fixed, variable, etc.), and per data segment encoding values. The per data segment encoding values include a total, or pillar width, number (T) of encoded data slices per encoding of a data segment (i.e., in a set of encoded data slices); a decode threshold number (D) of encoded data slices of a set of encoded data slices that are needed to recover the data segment; a read threshold number (R) of encoded data slices to indicate a number of encoded data slices per set to be read from storage for decoding of the data segment; and/or a write threshold number (W) to indicate a number of encoded data slices per set that must be accurately stored before the encoded data segment is deemed to have been properly stored. The dispersed storage error encoding parameters may further include slicing information (e.g., the number of encoded data slices that will be created for each data segment) and/or slice security information (e.g., per encoded data slice encryption, compression, integrity checksum, etc.).

In the present example, Cauchy Reed-Solomon has been selected as the encoding function (a generic example is shown in FIG. 4 and a specific example is shown in FIG. 5); the data segmenting protocol is to divide the data object into fixed sized data segments; and the per data segment encoding values include: a pillar width of five, a decode threshold of three, a read threshold of four, and a write threshold of four. In accordance with the data segmenting protocol, the computing device 12 or 16 divides the data (e.g., a file (e.g., text, video, audio, etc.), a data object, or other data arrangement) into a plurality of fixed sized data segments (e.g., 1 through Y of a fixed size in range of Kilo-bytes to Tera-bytes or more). The number of data segments created is dependent of the size of the data and the data segmenting protocol.

The computing device 12 or 16 then disperse storage error encodes a data segment using the selected encoding function (e.g., Cauchy Reed-Solomon) to produce a set of encoded data slices. FIG. 4 illustrates a generic Cauchy Reed-Solomon encoding function, which includes an encoding matrix (EM), a data matrix (DM), and a coded matrix (CM). The size of the encoding matrix (EM) is dependent on the pillar width number (T) and the decode threshold number (D) of selected per data segment encoding values. To produce the data matrix (DM), the data segment is divided into a plurality of data blocks and the data blocks are arranged into D number of rows with Z data blocks per row. Note that Z is a function of the number of data blocks created from the data segment and the decode threshold number (D). The coded matrix is produced by matrix multiplying the data matrix by the encoding matrix.

FIG. 5 illustrates a specific example of Cauchy Reed-Solomon encoding with a pillar number (T) of five and decode threshold number of three. In this example, a first data segment is divided into twelve data blocks (D1-D12). The coded matrix includes five rows of coded data blocks, where the first row of X11-X14 corresponds to a first encoded data slice (EDS 1_1), the second row of X21-X24 corresponds to a second encoded data slice (EDS 2_1), the third row of X31-X34 corresponds to a third encoded data slice (EDS 3_1), the fourth row of X41-X44 corresponds to a fourth encoded data slice (EDS 4_1), and the fifth row of X51-X54 corresponds to a fifth encoded data slice (EDS 5_1). Note that the second number of the EDS designation corresponds to the data segment number. In the illustrated example, the value X11=aD1+bD5+cD9, X12=aD2+bD6+cD10, . . . X53=mD3+nD7+oD11, and X54=mD4+nD8+oD12.

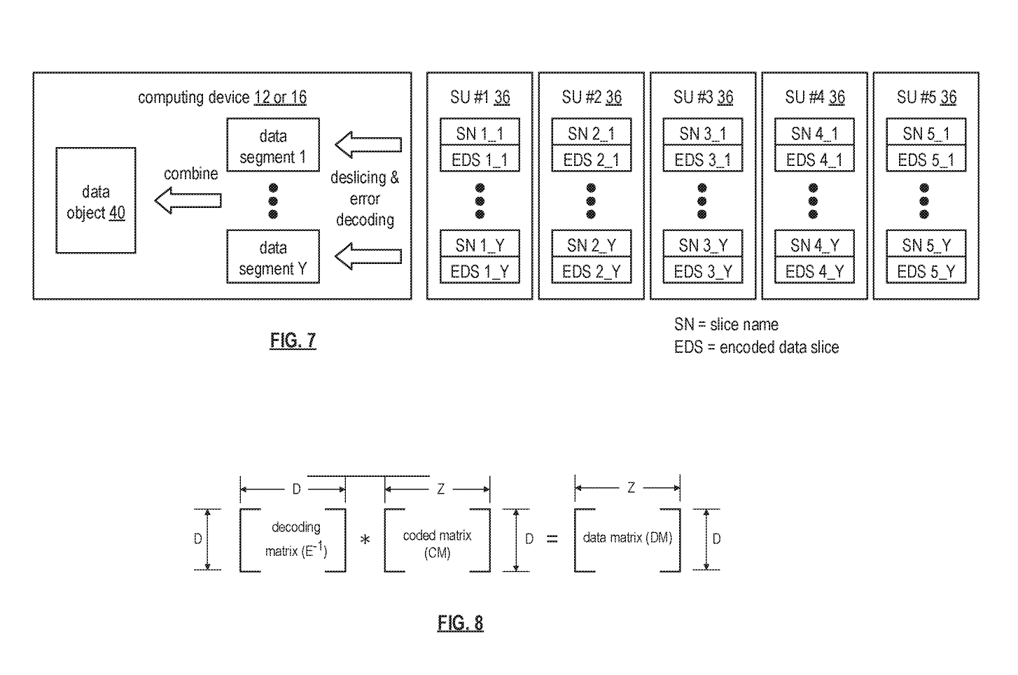

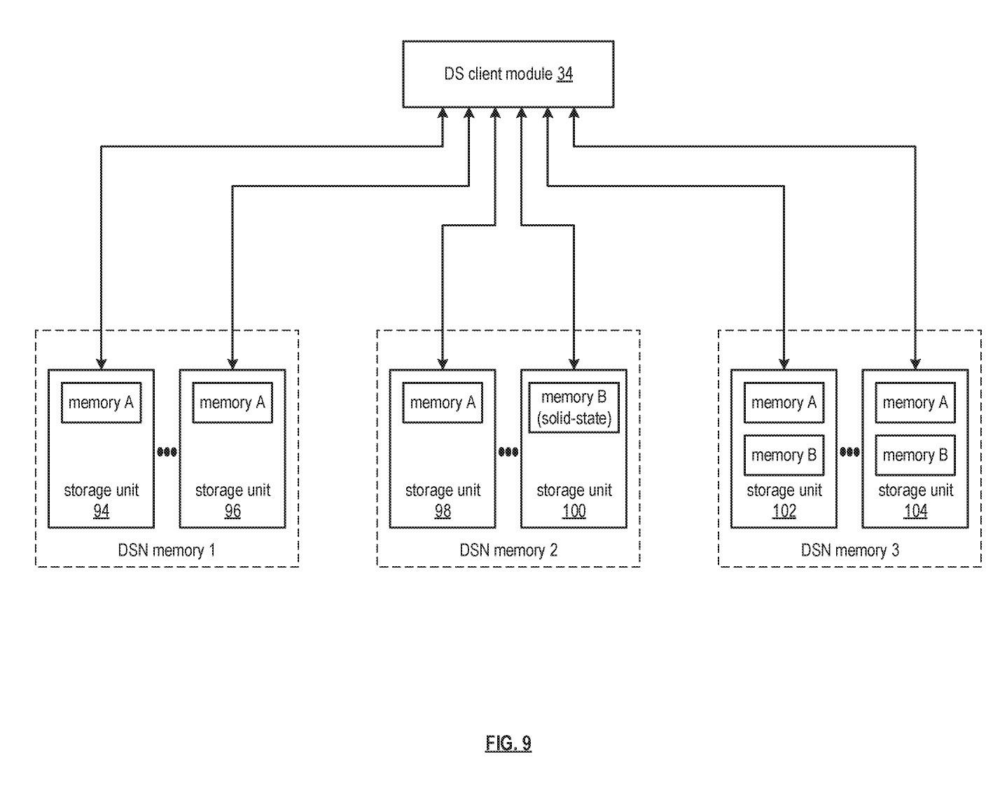

Returning to the discussion of FIG. 3, the computing device also creates a slice name (SN) for each encoded data slice (EDS) in the set of encoded data slices. A typical format for a slice name 80 is shown in FIG. 6. As shown, the slice name (SN) 80 includes a pillar number of the encoded data slice (e.g., one of 1−T), a data segment number (e.g., one of 1−Y), a vault identifier (ID), a data object identifier (ID), and may further include revision level information of the encoded data slices. The slice name functions as at least part of a DSN address for the encoded data slice for storage and retrieval from the DSN memory 22.

As a result of encoding, the computing device 12 or 16 produces a plurality of sets of encoded data slices, which are provided with their respective slice names to the storage units for storage. As shown, the first set of encoded data slices includes EDS 1_1 through EDS 5_1 and the first set of slice names includes SN 1_1 through SN 5_1 and the last set of encoded data slices includes EDS 1_Y through EDS 5_Y and the last set of slice names includes SN 1_Y through SN 5_Y.

FIG. 7 is a schematic block diagram of an example of dispersed storage error decoding of a data object that was dispersed storage error encoded and stored in the example of FIG. 4. In this example, the computing device 12 or 16 retrieves from the storage units at least the decode threshold number of encoded data slices per data segment. As a specific example, the computing device retrieves a read threshold number of encoded data slices.

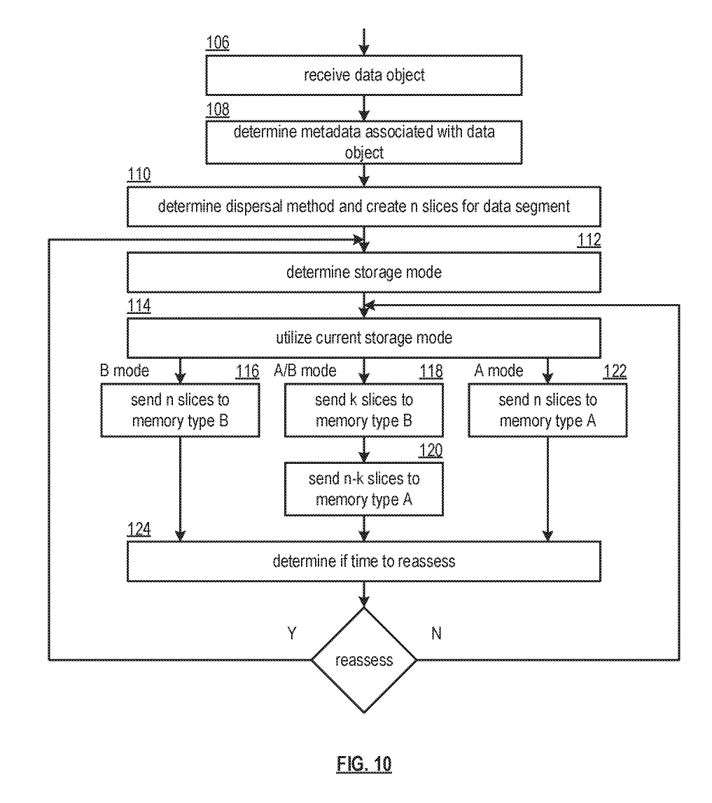

In order to recover a data segment from a decode threshold number of encoded data slices, the computing device uses a decoding function as shown in FIG. 8. As shown, the decoding function is essentially an inverse of the encoding function of FIG. 4. The coded matrix includes a decode threshold number of rows (e.g., three in this example) and the decoding matrix in an inversion of the encoding matrix that includes the corresponding rows of the coded matrix. For example, if the coded matrix includes rows 1, 2, and 4, the encoding matrix is reduced to rows 1, 2, and 4, and then inverted to produce the decoding matrix.

FIG. 9 is a schematic block diagram of another embodiment of a DSN in accordance with the present disclosure. In the illustrated DSN, a DS client module 34 (e.g., of a computing device 16) is operably coupled (e.g., via one or more networks) to a plurality of DSN (dispersed storage network) memory sites (e.g., DSN memory 1, a DSN memory 2, and a DSN memory 3) of the DSN memory 22. In this example, DSN memory site 1 includes one or more storage units 94-96 utilizing a memory A; DSN memory site 2 includes at least one storage unit 98 utilizing the memory A and at least one storage unit utilizing a memory B 100; and DSN memory site 3 includes at least one storage unit 102-104 utilizing the memory A and the memory B. Memory A and memory B may different types of memory (e.g., solid-state memory/drives and hard disk drives, two differing types of solid-state memory/drives, hybrid drives, etc.) having different memory characteristics, which are known to the DS client module 34 and/or to the storage units 94-104. The memory characteristics (also referred to herein as memory device characteristics) may include speed of access, cost, reliability, availability, capacity and other parameters. Each storage unit may be implemented utilizing the storage unit 36 of FIG. 1, and each of the storage units includes a DS client module 34 (not separately illustrated). The storage units of a storage set may be located at a same physical location (site) or located at multiple physical locations without departing from the technology as described herein.

In general, a DSN memory site stores a plurality of dispersed storage (DS) error encoded data. The DS error encoded data may be encoded in accordance with one or more examples described with reference to FIGS. 3-6, and organized (for example) in slice groupings or pillar groups. The data that is encoded into the DS error encoded data may be of any size and/or of any content. For example, the data may be one or more digital books, a copy of a company's emails, a large-scale Internet search, a video security file, one or more entertainment video files (e.g., television programs, movies, etc.), data files, and/or indexing and key information for use in dispersed storage operations.

In a dispersed storage network, it is natural for some stored data (also referred to herein as “data objects”) to be of greater importance and/or different size than other stored data. Often, the relative importance of a given piece of data is a dynamic property that evolves over time. Likewise, the performance and reliability of storage units and storage sets may vary. Some storage sets, such as those employing solid-state memory devices in accordance with the present disclosure, may provide relatively high performance, while others may be more suitable for long-term reliable storage of infrequently accessed data. Knowing the relative importance, size, frequency of access, etc. of data may be useful when determining appropriate resources for storing the data. As described more fully below in conjunction with the novel examples of FIGS. 9-14, differentiated levels of service within a DSN memory are enabled using rules and methods for data object storage and retrieval based on, for example, one or more of data object type and/or size, protocol, level of service associated with a user, security index, estimated storage time, updated metadata information, network traffic conditions, etc.

As noted, DSN memory according to the present disclosure may employ differing types of memory devices and technologies, including at least one type of solid-state memory (e.g., NAND-based, non-volatile flash memory). The solid-state memory may be arranged as a solid-state drive having no moving mechanical components and providing lower latency/access times than traditional hard disk drives.

Referring more particularly to FIG. 9, in an example of operation the DS client module 34 has a data object to store and determines (e.g., looks up, receives, retrieves from memory, etc.) storage metadata for the data object. The storage metadata includes storage requirements for the data object. The storage requirements include one or more of: a file type, file size, priority, security index, estimated storage time, estimated time between retrievals and more.

The DS client module 34 then determines (e.g., looks up, receives, retrieves from memory, etc.) memory device capabilities of the DSN memory 22. The memory device capabilities include a memory device storage cost, a memory device storage access speed, a memory device storage reliability, a memory device storage availability, and/or a memory device storage capacity. In this example, memory A has different memory device capabilities than memory B. For example, memory B may have a faster access speed than memory A.

The DS client module 34 then identifies memory devices of the DSN memory based on the memory device capabilities and the storage metadata to produce identified memory devices. For example, the DS client module 34 interprets the storage requirements of the metadata and attempts to match the requirements with the memory device capabilities. As a specific example, if the data object has a storage requirement for a fast access time, then the DS client module 34 would identify memory B for storage (as opposed to memory A in this example, which has a slower access time).

The DS client module 34 then encodes the data into a plurality of data slices in accordance with an error coding dispersal function and outputs the data slices to the identified memory devices for storage. For example, the slices are outputted to storage units 100-104 for storage in memory B.

In another example of operation, the DS client module 34 may choose to move previously stored data object slices from one memory type to another (e.g., from memory B to memory A). In this instance, the DS client module 34 interprets the storage metadata, which indicates that a fast data retrieval is no longer required, and initiates the data transfer. The data transfer may be a straight transfer of the data slices from memory B to memory A, or may be done by reconstructing the data object from the slices in memory B, re-encode the reconstructed data object using the same or different operational parameters of the error coding dispersal storage function to produce re-constructed slices, and storing the reconstructed slices in memory A.

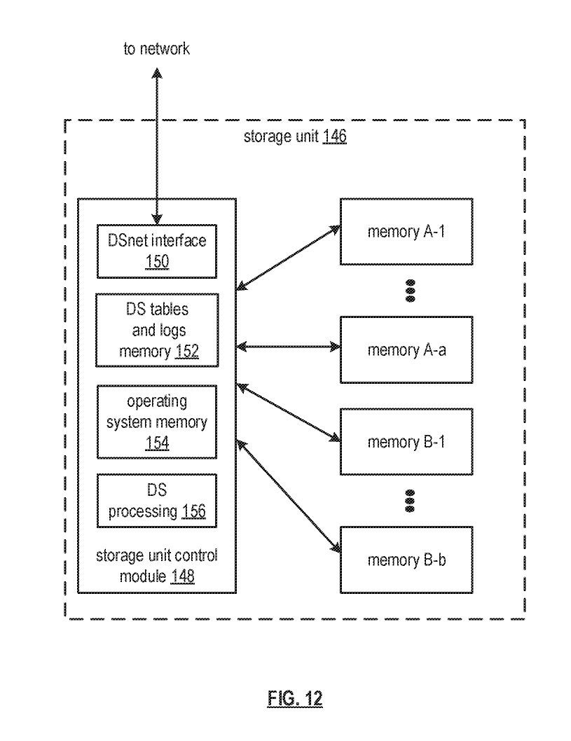

FIG. 10 is a logic diagram of an example of determining data distribution in accordance with the present disclosure. In the illustrated example, a computing device/DS client module may choose the memory, create encoded data slices, and send the slices for storage to the chosen memory. The method begins at step 106 where the DS client module receives a data object from a source (e.g., a user device, an integrity processing unit, another computing device, a storage unit, and/or a DS managing unit). The method continues at step 108 where the DS client module determines the storage metadata (e.g., a file type, file size, priority, security index, estimated storage time, estimated time between data access operations, etc.) associated with the data object. Such a determination is based on one or more of the data itself, information received with the data object, information derived from generation of the data object, a command, a message, and/or a predetermination. Alternatively, or in addition to, the determination may be based on segmenting the data in accordance with an error coding dispersal function to produce a plurality of data segments followed by subsequent determination of the storage metadata based on at least one of the plurality of data segments. As yet another alternative or addition, the determination may be based on partitioning the data based on customized data content (e.g., user preferences and/or files) and generic data content (e.g., a commonly available application) to produce a customized data partition and a generic data partition followed by the subsequent determination of customized data partition storage metadata regarding the customized data partition and generic data partition storage metadata regarding the generic data partition followed by aggregation of the customized data partition storage metadata and the generic data partition storage metadata to produce the storage metadata.

The method continues at step 110 where the DS client module determines a storage dispersal method (e.g., operational parameters for an error coding dispersal storage function). The operational parameters include one or more of: a pillar width, a read threshold, an error coding algorithm, an encryption algorithm, a slicing parameter, a compression algorithm, an integrity check method, a caching settings, and a parallelism settings. Within step 110, the DS client module encodes the data segment in accordance with the storage dispersal method to produce a plurality of error coded data slices 1−n (which may also be referred to as encoded data slices, data slices or slices). For example, the metadata may require high reliability and fast retrieval speeds for a relatively short period of time. In this example, the DS client module would select a storage dispersal method to include a low number pillars (e.g., X) using a certain type of memory device, such as solid-state memory device(s)/solid-state drive(s) to speed subsequent retrieval.

The method continues at step 112 where the DS client module determines a storage mode based on the metadata and memory capabilities of the DSN memory. The storage mode includes a memory selection and may further include a time phase indicator. The time phase indicator specifies one or more time intervals for a given set of storage requirements. For example, the time phase indicator specifies a first time phase that corresponds to a time period from the initial storage of the new data object and second time phase that corresponds to the time period after the first time phase expires. As a specific example, the DS client module determines the storage mode to be a B mode (e.g., fast and reliable solid-state storage) for the first time phase and storage mode A for the second time phase.

The DS client module may also determine the storage mode based on the type of data. For example, the data may include customized data content (e.g., user preferences and/or files) and/or generic data content (e.g., a commonly available application). In this example, the generic data content may have one type of storage mode (e.g., slower, less reliable, etc.), while the customized data content may have another type of storage mode (e.g., faster, more reliable, etc.).

The method continues at step 114 where the DS client module utilizes the current storage mode to store slices 1−n in the DSN memory. In this instance, the DS client module looks up the mapping in a virtual DSN address to physical location table (e.g., a table maintained by the DS client module, a higher-level controller or one or more storage units) to determine where the slices should be stored. Note that the virtual DSN address to physical location table may include both the current storage mode and the last storage mode to facilitate moving slices from the memory of the last mode to the memory in accordance with the current storage mode.

When the storage mode is mode B, the method continues to step 116 where the DS client module sends the data slices to storage units with memory type B. When the storage mode is mode A, the method continues to step 122 where the DS processing sends the data slices to storage units with memory type A. Note that such decisions may be made on a data segment by data segment basis or for groupings of data segments (e.g., a data file).

When the storage mode is mode A/B, the method continues at step 118 where the DS client module sends k slices (e.g., a read threshold number of slices) to storage units with memory type B 118 and, at step 120, sends the other n-k slices to storage units with memory type A. Note that this scenario may include the metadata-indicated requirement for fast access (without failures), reliable memory with some cost constraint for the current time phase. Further note that when k is equal to or is greater than the read threshold, the DS client module can retrieve slices from the memory B without retrieving slices from memory A unless one or more slices from memory B is missing or corrupt.

After storing the slices, the method continues at step 124 where the DS client module determines whether it is time to reassess the storage mode. Such a determination may be based on one or more of an elapsed period of time since the current storage mode was established, there have been no retrievals of the data object within a time period, a command, a request, and/or a memory type is filling up (e.g., memory B). Note that a likely scenario is starting with the B mode (e.g., fast and frequent data retrievals from flash memory or RAM), transition to the A/B mode (e.g., less frequent, but still fast data retrievals), and then transition and remain at in mode A (e.g., less frequent and slower data retrievals).

Alternatively, or in addition to, the reassessing may be based on the occurrence of a condition to update the identification of the memory devices. The condition may include one or more of, but not limited to, updating of the storage metadata, a change of memory device characteristics, a change of available memory devices, and/or an occurrence of a triggering event. For example, the processing module may determine that the condition has occurred to update the dedication of the memory devices when new memory devices with more favorable memory characteristics relative to the storage requirements are available. The method continues with the step where the processing module re-identifies memory devices when the condition has occurred. In such an instance, the processing module may retrieve a portion of the plurality of data slices and facilitate moving the plurality of data slices to the re-identified memory devices.

If not reassessing, the method repeats at step 114. If reassessing, the method continues step 112 where the DS client module determines whether to change the storage mode, such as changing from storage mode B to storage mode A/B or to storage mode A. Other changes of the storage mode may also be determined, such as to change an operational parameter of the error coding dispersal storage function (e.g., number of pillars), which would revert the method to step 110.

FIG. 11 a logic diagram of another example of determining data distribution in accordance with the present disclosure. The illustrated method begins at step 126 where the DS client module receives a data object from a source (e.g., a user device, the storage integrity processing unit, another computing device, the storage unit, or the DS managing unit). The method continues at step 128 where the DS client module determines metadata associated with the data object, which may be done in a similar manner as discussed with reference to step 108 of FIG. 10.

The method continues at step 130 where the DS client module determines a first dispersal method in a manner similar to step 110 of FIG. 10. In addition, the DS client module determines to store the slices in a storage units having a first type (e.g., solid-state) of memory, such as memory having a first set of memory capabilities. The method continues at step 132 where the DS client module sends the slices to the storage units with the first memory type.

The method continues at step 134 where the DS client module determines whether it is time to move the slices from the first type of memory device to a second type of memory device. Such a determination may be based on one or more of, but not limited to, an elapsed time period of storage in the first type of memory, an elapsed time period since a data slice retrieval from the first type of memory, a first type of memory utilization indicator, a command, and/or a request. For example, a processing module may determine to transfer the plurality of data slices when the processing module determines that the elapsed time period of storage in the first type of memory exceeds a storage threshold.

The method repeats at step 134 when it is not time to move the slices. When it is time to move the slices, the method continues at step 136 where the DS client module retrieves the slices from the storage units having memory of the first memory type. The method then continues at step 137 where the DS client module determines whether to reconstruct data from the data slices. Such a determination may be based on the type of data, the second memory type, a change in the storage requirements (e.g., archiving, reduced retrieval needs, etc.), change in the operational parameters of the error coding dispersal storage function, and/or any other factor that would require the data to be reconstructed.

When the data is to be reconstructed, the method continues at step 138 the DS client module reconstructs at least a portion of the data from the plurality of data slices in accordance with a first error coding dispersal function to produce reconstructed data. The first error coding dispersal function includes one or more of but not limited to an error coding type that includes at least one of an error coding algorithm, an encryption algorithm, and a compression algorithm and operational parameters that include two or more of a pillar width, a read threshold, a slicing parameter, an integrity check method, a caching settings, and a parallelism settings.

The method continues to step 139 where the DS client module determines a second dispersal method (e.g., a second error coding dispersal storage function and identify the storage units having memory of the second type). The second error coding dispersal function includes one or more of, but not limited to, an error coding type that includes at least one of an error coding algorithm, an encryption algorithm, and a compression algorithm and operational parameters that include two or more of a pillar width, a read threshold, a slicing parameter, an integrity check method, a caching settings, and a parallelism settings. In an example, the second error coding dispersal function may include the error coding type that is substantially the same as the error coding type of the first error coding dispersal function. In another example, the second error coding dispersal function may include a different error coding type than that of the first error coding dispersal function. In yet another example, the second error coding dispersal function may include operational parameters that are substantially the same as the operational parameters of the first error coding dispersal function. In further example, the second error coding dispersal function may include different operational parameters than that of the first error coding dispersal function.

The method continues to step 140 where the DS client module encodes the reconstructed data into a second plurality of slices in accordance with the second error coding dispersal storage function. The method continues at step 142 from step 140 (or from step 137 when the data is not to be reconstructed) where the DS client module sends the slices (e.g., the original ones or the new ones) to storage units having memory of the second type. The method continues at step 144 where the DS client module updates the virtual DSN address to physical location table to reflect where the slices are now stored. Note that the method of FIG. 11 may be applied on a data segment by data segment basis or for group of data segments (e.g., a data file). In the latter case, pluralities of data slices may be processed to reconstruct the data (e.g., reconstruct the data file) and then the reconstructed data (e.g., data file) is encoded to produce pluralities of slices encoded in accordance with the second error coding dispersal storage function.

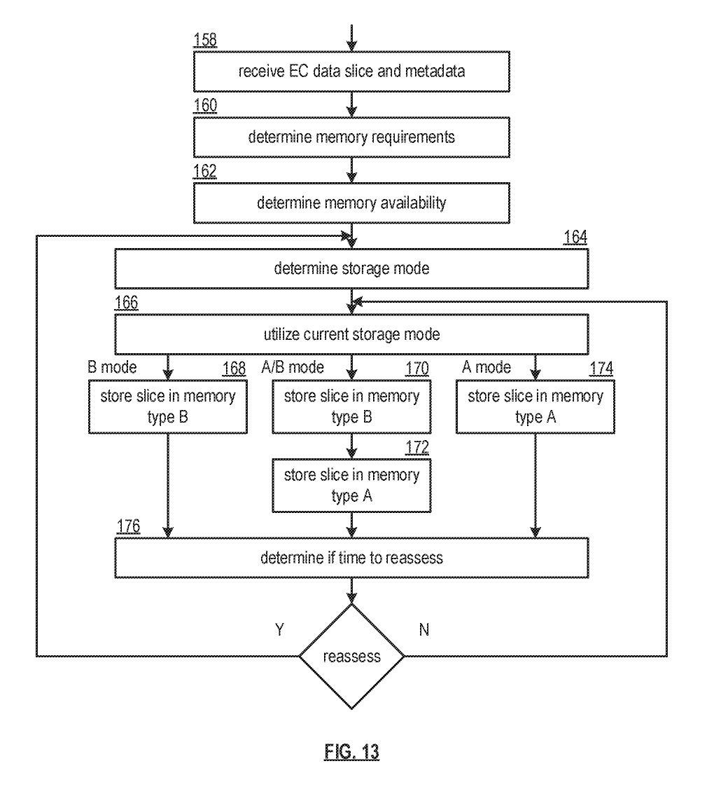

FIG. 12 is a schematic block diagram of an embodiment of a distributed storage unit 146 (e.g., storage unit 36 and/or 95-104) in accordance with the present disclosure. The illustrated storage unit 146 includes a storage unit control module 148, a plurality of memories of type A (1−a), and a plurality of memories of type B (1−b). The storage unit control module 148 includes the DSnet interface 150, an internal memory for DS tables and logs (operational data memory) 152, a memory for the operating system (OS) 154, and the DS processing 156 (e.g., a DS client module 34). The storage unit control module 148 may be operably coupled to the computing system via the DSnet interface 150 via the network.

The memories may be implemented as memory devices that are included in the storage unit 146 and/or outside of the storage unit 146. The memory devices may include but not limited to one or more of a magnetic hard disk, a solid-state disk (SSD) based on NAND-based flash or other type of integrated circuit technology, read only memory, optical disk, and/or any other type of read-only, and/or read/write memory. For example, memory A-1 may be implemented in the storage unit 146 and memory A-2 may be implemented in a remote server (e.g., a different storage unit operably coupled to the storage unit 146 via the network). In an example, memory A-1 through memory A-a are implemented with the magnetic hard disk technology and memory B-1 through memory B-b are implemented with the NAND-based flash (or other type of solid-state) technology. The memory devices may be associated with one or more memory device characteristics. Memory device characteristics may include one or more of but not limited to a memory device storage cost, a memory device storage access speed, memory device storage reliability, memory device storage availability, and/or a memory device storage capacity. The memory devices may further comprise main memory 54, a local non-main memory, and/or a non-local non-main memory.

The operational data memory 152 may be utilized to store operational data. The storage unit operational data may include one or more of but not limited to a DS table, a local virtual distributed storage network (DSN) address to physical memory table, a log, an activity record, a memory utilization record, an error record, a storage record, a retrieval record, and/or a vault information record. In other words, the storage unit operational data may be data that is used from time to time to operate the storage unit 146. The operating system memory 154 may be utilized to store a storage unit operating system algorithm. The storage unit operating system algorithm may include at least a portion of operating system executable software that is utilized to operate the storage unit.

In an example of a write operation, the DS processing module 156 of the storage unit receives an encoded slice to store. For example, the storage unit may receive an encoded slice from a user computing device 12 for storage in the storage unit. The DS processing module 156 then determines if the storage unit operating system is running. If so, the DS processing module 156 selects one of the plurality of memory devices for storing the encoded slice when the DS processing module 156 determines that the storage unit operating system is running. The DS processing module 156 may retrieve slices of at least a portion of the operating system from one or more of the memories when the DS processing module 156 determines that the operating system is not running. The DS processing module 156 may decode the retrieved slices of the at least a portion of the operating system in preparation for execution as required.

The DS processing module 156 then selects one of the plurality of memory devices for storing the encoded slice to produce a selected memory device based on one or more of, but not limited to, metadata associated with the encoded slice and a memory-based storage mode. The memory-based storage mode may include the memory selection and a time phase indicator. Such a selection may be based on one or more of the metadata, a command (e.g., from a computing device indicating which memory type to use), a type of data indicator, a priority indicator, available memory, memory performance data, memory cost data, and/or any other parameter to facilitate desired levels of efficiency and performance. For example, the storage unit control module 148 may choose memory A-1 (e.g., a magnetic hard disk drive) to store the received encoded slice since the performance and efficiency is good enough for the encoded slice requirements (e.g., availability, cost, response time). In another example, the storage unit control module 148 distributes slices across the storage unit memories. In another example, the storage unit control module 148 distributes a read threshold k of the slices across memory B (e.g., SSD(s) for fast retrieval) and the other n-k slices across memory A. In yet another example, the storage unit control module 148 distributes the slices across the storage unit memories and at least one other storage unit at the same site as the storage unit 146. In yet another example, the storage unit control module 148 distributes the slices across the storage unit memories and at least one other storage unit at a different site as the storage unit 146.

The DS processing module 156 may determine if the operational data memory 152 is available. The DS processing module 156 may utilize the operational data from the operational data memory 152 when the DS processing module 156 determines that the operational data memory 152 is available. In an alternative, the DS processing module 156 may select one of the memory devices of the storage unit by retrieving data slices of the storage unit operational data from the memory devices to produce retrieved data slices when the DS processing module 156 determines that the operational data memory 152 is not available. The DS processing module 156 reconstructs vault information from the retrieved data slices in accordance with the error coding dispersal storage function. The DS processing module 156 selects one of the memory devices based on the vault information. In other words, the DS processing module 156 retrieves operational data to determine where to store the encoded slice. DS processing module 156 may update the operational data to produce updated operational data. The DS processing module 156 may encode the updated operational data to produce updated vault information data slices in accordance with the error coding dispersal storage function. The DS processing module 156 may then store the updated vault information data slices in the memory devices, and store the received encoded slice in the selected memory device. The DS processing module 156 may further change the status of the operational data memory 152 to unavailable, and deactivate the storage unit operating system and/or the operating system memory 154.

In an example of a read operation, the DS processing module 156 receives a read request for an encoded data slice. For example, the DS processing module 156 may first determine if the storage unit operating system is running. If so, the DS processing module 156 may then determine if the storage unit operating system is running.

If the operational data memory 152 is available, the DS processing module 156 may then retrieve slices of at least a portion of the operating system from one or more of the memories when the DS processing module 156 determines that the operating system is not running. The DS processing module 156 decodes the retrieved slices of the at least a portion of the operating system in preparation for execution as required.

The DS processing module 156 may then determine if the operational data memory 152 is available. If so, the DS processing module 156 may utilize the operational data (e.g., identifying which memory device contains the encoded data slice to be retrieved) from the operational data memory 152. The DS processing module 156 may select one of the memory devices of the storage unit where the encoded data slices are stored by retrieving data slices of the storage unit operational data from the memory devices to produce retrieved data slices when the DS processing module 156 determines that the operational data memory 152 is not available. The DS processing module 156 reconstructs vault information from the retrieved data slices in accordance with the error coding dispersal storage function. The DS processing module 156 selects one of the memory devices based on the vault information. In other words, the DS processing module 156 retrieves operational data to determine where to retrieve the encoded slice.

The DS processing module 156 next determines which memory device contains the encoded data slice to be retrieved based on the operational data, and retrieves the encoded data slice from the selected memory device. The DS processing module 156 then outputs the encoded data slice to a requester via the DSnet interface 150. The DS processing module 156 may also change the status of the operational data memory 152 to unavailable, and deactivate the storage unit operating system and/or the operating system memory 154.

In an example of a slice transfer operation, the DS processing module 156 receives a request to transfer a slice from a first memory type to a second memory type. The DS processing module 156 first determines if the storage unit operating system is running and if the operational data memory 152 is available. When the operational data memory 152 is available, the DS processing module 156 may retrieve slices of at least a portion of the operating system from one or more of the memories when the DS processing module 156 determines that the operating system is not running. The DS processing module 156 may decode the retrieved slices of the at least a portion of the operating system in preparation for execution as required.

The DS processing module 156 may next determine if the operational data memory 152 is available. If so, the DS processing module 156 utilizes the operational data (e.g., which memory device contains the encoded data slice to be transferred) from the operational data memory 152. The DS processing module 156 may select one of the memory devices of the storage unit where the encoded data slices are stored by retrieving data slices of the storage unit operational data from the memory devices to produce retrieved data slices when the DS processing module 156 determines that the operational data memory 152 is not available. The DS processing module 156 reconstructs vault information from the retrieved data slices in accordance with the error coding dispersal storage function. The DS processing module 156 selects one of the memory devices based on the vault information. In other words, the DS processing module 156 retrieves operational data to determine where to retrieve the encoded slice.

Next, the DS processing module 156 determines which memory device contains the encoded data slice to be retrieved based on the operational data, and retrieves the encoded data slice from the selected memory device. The DS processing module 156 further determines which memory to transfer the encoded data slice to in response to the requester transfer. The determination may be based on one or more of an elapsed time period since the last store, a command, an error message, a change in the memory architecture (e.g., a new memory device is added), and/or at least one of the DS tables, logs, and OS have changed. Having determined where to store the slice, the DS processing module 156 stores the slice in the selected memory. The DS processing module 156 updates and maintains a local virtual DSN address to physical memory table in the operational data memory 152. The table maintains a record of where the slices are physically stored in the memories and associated the physical location to the slice name. The DS processing module 156 may also change the status of the operational data memory 152 to unavailable, and deactivate the storage unit operating system and/or the operating system memory 154.

Note that the storage unit control module 148 may utilize the DS processing module 156 to distributedly store the DS tables, logs, and OS (e.g., that also utilize internal memory of the storage unit control module 148) to improve the reliability of operation of the storage unit 146. The storage unit 146 may subsequently retrieve and restore one or more of the DS tables, logs, and OS. The storage unit control module 148 may be configured to determine when to distributedly store one or more of the DS tables, logs, and OS.

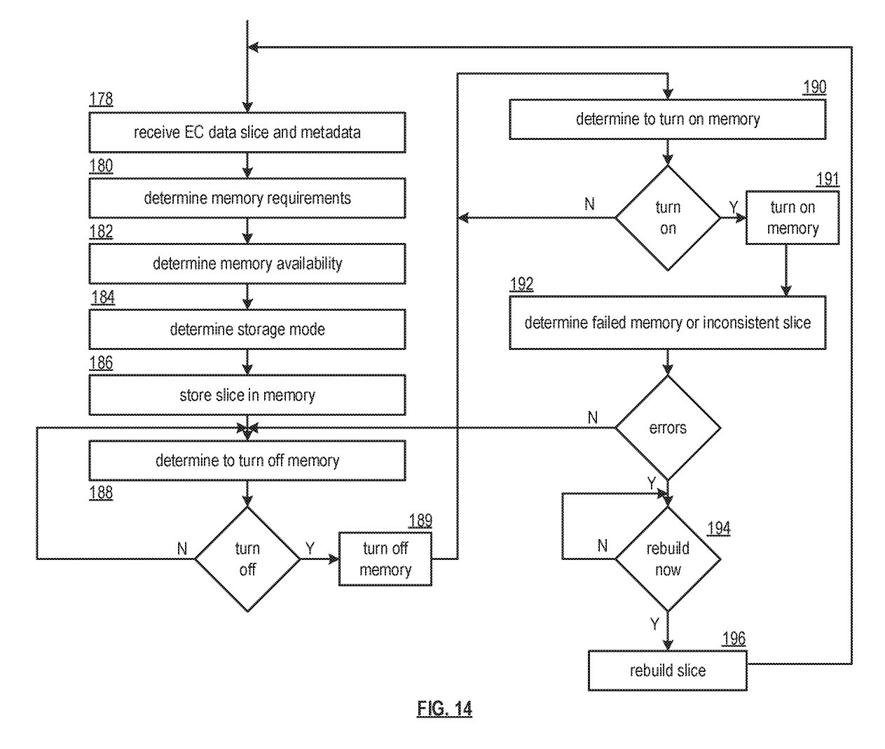

FIG. 13 is a logic diagram of another example of determining data distribution in accordance with the present disclosure. In the illustrated example, a processing module (e.g., a DS processing module 156 of a storage unit) may choose a memory to store a new slice and/or subsequently move a slice. The method begins at step 158 where the processing module receives, via an interface module, an encoded data slice and metadata from a source (e.g., a user device, the storage integrity processing unit, the computing device, another storage unit, and/or the managing unit 18). The computing device (e.g., or another device with DS processing capabilities) may have created the metadata associated with the data object as previously discussed with reference to FIG. 10.

The method continues at step 160 where the processing module determines memory requirements based on the metadata. For example, the metadata may indicate a very high reliability requirement and a fast retrieval speed requirement for a short-term period. The processing module may subsequently choose the memory device(s) (e.g., solid-state memory device(s)) that best matches the requirements.

The method continues at step 162 where the processing module determines memory availability. The determination may be based on one or more of but not limited to a query, a command, a message, and error message, and/or a table lookup. In an example, the processing module may retrieve a plurality of data slices from at least some of the plurality of memory devices based on the encoded slice. In other words, the processing module retrieves a plurality of data slices that are associated with the encoded slice, such as via a shared vault identity. The processing module reconstructs DS operational data from the plurality of data slices in accordance with an error coding dispersal storage function. The DS operational data may include one or more of but not limited to a DS table, a local virtual distributed storage network (DSN) address to physical memory table, a log, an activity record, a memory utilization record, an error record, a storage record, a retrieval record, a vault information record. Within step 162 the processing module may further determine memory characteristics based on retrieving information previously stored in DS tables.

The method continues at step 164 where the processing module determines a storage mode based on the metadata and memory capabilities of the storage unit. The storage mode includes a memory selection and may further include a time phase indicator. The time phase indicator specifies one or more time intervals for a given set of storage requirements. For example, the time phase indicator specifies a first time phase that corresponds to an elapsed period of time from the initial storage of the new data object and second time phase that corresponds to the time period after the first time phase expires. As a specific example, the processing module determines the storage mode to be a B mode (e.g., fast and reliable solid-state memory) for the first time phase and storage mode A for the second time phase.

The processing module may also determine the storage mode based on the type of data. For example, the data may include customized data content (e.g., user preferences and/or files) and/or generic data content (e.g., a commonly available application). In this example, the generic data content may have one type of storage mode (e.g., slower, less reliable, etc.), while the customized data content may have another type of storage mode (e.g., faster, more reliable, etc.).

The method continues at step 166 where the processing module utilizes the current storage mode to store slices in the storage unit. In this instance, the processing module mapping information in the DS operational data (e.g., a local virtual DSN address to physical location table) to determine where the slice should be stored. Note that the virtual DSN address to physical location table may include both the current storage mode and the last storage mode to facilitate moving slices from the memory of the last mode to the memory in accordance with the current storage mode.

When the storage mode is mode B, the method continues to step 166 where the processing module stores the data slice to a memory device with memory type B. When the storage mode is mode A, the method continues to step 174 where the DS processing stores the data slice to a memory device with memory type A. Note that such decisions may be made on a data segment by data segment basis, or for groupings of data segments (e.g., a data file).

When the storage mode is mode A/B, the method continues at step 170 where the processing module stores the data slice to the memory device with memory type B and, at step 172, stores the data slice to the memory device with memory type A. This scenario may include the metadata-indicated requirement for fast access (without failures) and reliable memory with some cost constraint for the current time phase. In other words, the data slice may be subsequently retrieved from the memory device of either memory type A or memory type B in accordance with a retrieval requirement.

After storing the slices, the method continues at step 176 where the processing module determines whether it is time to reassess the storage mode. Such a determination may be based on one or more of a time period has elapsed since the current storage mode, there have been no retrievals of the data slice within a time period, a command, a request, and/or a memory type is reaching capacity (e.g., memory B). Note that a likely scenario is starting with the B mode (e.g., fast and frequent data retrievals from solid-state memory), transition to the A/B mode (e.g., less frequent, but still fast data retrievals), and then transition and remain in mode A (e.g., less frequent and slower data retrievals).

Alternatively, or in addition to, reassessing the storage mode may be based on the occurrence of a condition to update the identification of the memory devices. The condition may include one or more of, but not limited to, updating of the storage metadata, a change of memory device characteristics, a change of available memory devices, and/or an occurrence of a triggering event. For example, the processing module may determine that the condition has occurred to update the identification of the memory devices when new memory devices with more favorable memory device characteristics relative to the storage requirements are available. The method continues with the step where the processing module re-identifies memory devices when the condition has occurred. In such an instance, the processing module may retrieve data slice and facilitate relocation of the data slice to the re-identified memory device.

If not reassessing, the method repeats at step 166. If reassessing, the method continues step 164 where the processing module determines whether to change the storage mode (e.g., from storage mode B to storage mode A/B or to storage mode A).

FIG. 14 is a logic diagram illustrating an example of memory device management in accordance with the present disclosure. In the illustrated example, a processing module (e.g., a DS processing module 156 of a storage unit) may power down a memory device that is infrequently utilized to extend the operational life of the memory device.

In an embodiment, the storage unit previously discussed with reference to FIG. 12 includes a plurality of memory devices. The plurality of memory devices includes a first set of memory devices (e.g., memory devices A-1 to A-a) that are continually active and a second set of memory devices (e.g., memory devices B-1 to B-b) that are selectively active. In an instance, the first set of memory devices store first data having a rate of retrieval in a first interval retrieval rate range and the second set of memory devices store second data having a rate of retrieval in a second interval retrieval rate range. For example, the first set of memory devices (e.g., solid-state memory devices) may be utilized when data is retrieved at a higher rate than the data retrieved from the second set of memory devices. In an example, data is archived utilizing the second set of memory devices such that at least one memory device of the first set of memory devices may be de-activated from time to time (or vice versa). Note that the de-activation of a memory device may provide the system with improved reliability and/or power savings.

In an example of a store operation, the method begins with step 178 where the processing module 156 of the storage unit 146 receives an encoded slice and metadata from a source (e.g., a user device, a storage integrity processing unit, a computing device, another storage unit, or a DS managing unit). The computing device (e.g., or another unit with DS processing capabilities) creates the metadata associated with the data object as previously discussed.

The method continues with step 180 where the processing module determines memory requirements as discussed with reference to step 160 of FIG. 13. For example, the metadata may indicate a very high reliability requirement and a fast retrieval speed requirement for a relatively short period of time (e.g., that corresponds to an estimated period of high demand). In another example, the metadata may indicate a very long period of storage with few retrieval requirements (e.g., a records archive). The processing module may subsequently choose the memory that best matches those requirements as described below.

The method continues with step 182 where the processing module determines memory availability as discussed with reference to step 162 of FIG. 13. The method continues with step 184 where the processing module determines the storage mode based on one or more of but not limited to the memory requirements, the memory availability, and/or memory characteristics. The storage mode may include the memory selection and a time phase indicator. The time phase may include a first phase to include the time period between the initial storage of the new slice until the time when the memory is to be powered off. Note that other time phases may comprise a subsequent phase to include the time period between the last power down until the time when the memory power is to be turned back on to perform memory tests. For example, the processing module determines the storage mode to be a long-term archive following a ten-day period from initial storage of the slice, when subsequent retrievals may be frequent. The processing module may update the local virtual DSN address to physical location table to reflect where the slice will be stored.

The method continues with step 186 where the processing module stores the encoded slice in one of the second set (for example) of memory devices. The processing module may de-activate the one of the second set of memory devices, in accordance with a deactivation protocol, after storing the encoded slice. The deactivation protocol may include one or more of, but not limited to, the elapsed time since storage of the encoded slice in the one of the second set of memory devices, the elapsed time since a retrieval request for the encoded slice, elapsed active state time of the one of the second set of memory devices, a command, an irregular power indicator, an earthquake indicator, a bad weather indicator, a retrieval frequency indicator, and/or an indicator to improve the life of the memory device.

In another embodiment, the processing module stores the encoded slice in the one of the first set of memory devices when the encoded slice is to be stored in the one of the first set of memory devices. The processing module may determine whether to transfer the encoded slice from the one of the first set of memory devices to the one of the second set of memory devices based a data transfer protocol (e.g., based on a specified time period, a condition of transfer, etc.). For example, the processing unit may determine to transfer the encoded slice when a time period has elapsed since initial storage of the encoded slice in the one of the first set of memory devices. The processing unit may retrieve the encoded slice from the one of the first set of memory devices and store the encoded slice in the one of the second set of memories when the processing unit determines that the encoded slice is to be transferred.

The method continues with step 188 where the processing module determines when to de-activate (e.g., turn off) the memory device to produce a de-activated memory device. The determination may be based on one or more of, but not limited to, the elapsed time since a retrieval request for at least a portion of the second data, the elapsed time since a store request for at least a portion of the second data, the elapsed active state time of the memory device, a command, an irregular power indicator, an earthquake indicator, a bad weather indicator, a retrieval frequency indicator, and/or an indicator to improve the life of the memory device. If not turning off the memory, the method repeats at step 188. If turning off the memory, the method continues to step 189 where the processing module turns off the memory.

The method continues with step 190 where the processing module determines when to activate (e.g., turn on) the memory. The processing module determines when to activate the memory device (e.g., of the second set) based on one or more of, but not limited to, a retrieval request for at least a portion of the second data, the elapsed inactive state time of the memory device of the second set, a command, an irregular power indicator, an earthquake indicator, a bad weather indicator, a retrieval frequency indicator, and/or an indicator to improve the life of the memory device. Note that the memory may be activated to perform integrity and consistency checks of the stored slices. If not turning on the memory, the method repeats at step 190. If turning on the memory, the method continues to step 191 where the processing module turns on the memory. The processing module may also retrieve the encoded slice and/or slice information from the activated memory device. The slice information may include one or more of but not limited to an encoded slice, content data, error control information, a hash of a slice name list, a slice name list, a source name list, a hash of a source name list, and/or a slice revision.

The method continues with step 192 where the processing module determines whether the retrieved encoded slice has an error (e.g., failed memory or slice inconsistency). The determination may be based on one or more of, but not limited, to a missing slice test, an outdated slice revision test, a slice name comparison to at least one other slice name from a slice name list, a slice revision comparison to at least one other slice revision from a slice revision list, a slice name comparison to at least one other slice name from another storage unit, a slice revision comparison to at least one other slice revision from another storage unit, and/or a stored checksum comparison to a re-calculated checksum.

The method returns to step 188 to determine when to turn the memory off when the processing module does not detect any errors. In this instance, the processing module may determine a condition for the previous activation of the memory device when the retrieved encoded slice does not have an error. In other words, the processing module determines why the memory device was activated (e.g., to check for errors and/or to retrieve an encoded slice). For example, the processing module sends, via an interface module, the retrieved encoded slice and initiates deactivation of the memory device when the condition was a data access request (e.g., to retrieve an encoded slice). The processing module may likewise initiate deactivation of the memory device when the condition was verification-based (e.g., to check for errors).

When the processing module detects errors, the method continues to step 194 where the processing module determines when to rebuild the slices with errors. The rebuild determination may be based on one or more of memory device availability (e.g., a replacement hard disk drive may need to be installed), a command, a timer, and/or a substitute memory becoming available. If not rebuilding, the method repeats at step 194. If rebuilding, the method continues to step 196 where the processing module rebuilds and stores the recreated slice. For example, the processing module retrieves good slices of the same segment from the other pillar storage units, and de-slices and decodes the slices to produce the original data object. The processing module recodes and re-slices the original data object to produce repaired slices to replace the one or more slices that were in error. The processing module stores the repaired slices in the storage unit memory and updates the local virtual DSN address to physical location table if there are changes (e.g., when a substitute memory is utilized). The processing module may then deactivate the activated memory device (e.g., immediately or on a delayed basis).

The methods (or portions thereof) described above in conjunction with the storage units can alternatively be performed by other modules (e.g., DS client modules 34) of a dispersed storage network or by other devices (e.g., managing unit 18 or integrity processing unit 20). Any combination of a first module, a second module, a third module, a fourth module, etc. of the computing devices and the storage units may perform the method described above. In addition, at least one memory section (e.g., a first memory section, a second memory section, a third memory section, a fourth memory section, a fifth memory section, a sixth memory section, etc. of a non-transitory computer readable storage medium) that stores operational instructions can, when executed by one or more processing modules of one or more computing devices and/or by the storage units of the dispersed storage network (DSN), cause the one or more computing devices and/or the storage units to perform any or all of the method steps described above.

As may be used herein, the terms “substantially” and “approximately” provides an industry-accepted tolerance for its corresponding term and/or relativity between items. Such an industry-accepted tolerance ranges from less than one percent to fifty percent. Such relativity between items ranges from a difference of a few percent to magnitude differences. As may also be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”. As may even further be used herein, the term “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item.

As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1. As may be used herein, the term “compares unfavorably”, indicates that a comparison between two or more items, signals, etc., fails to provide the desired relationship.

As may also be used herein, the terms “processing module”, “processing circuit”, “processor”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, and/or processing unit may be, or further include, memory and/or an integrated memory element, which may be a single memory device, a plurality of memory devices, and/or embedded circuitry of another processing module, module, processing circuit, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, and/or processing unit executes, hard coded and/or operational instructions corresponding to at least some of the steps and/or functions illustrated in one or more of the Figures. Such a memory device or memory element can be included in an article of manufacture.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from Figure to Figure, the embodiments may incorporate the same or similarly named functions, steps, modules, etc. that may use the same or different reference numbers and, as such, the functions, steps, modules, etc. may be the same or similar functions, steps, modules, etc. or different ones.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

As may further be used herein, a computer readable memory includes one or more memory elements. A memory element may be a separate memory device, multiple memory devices, or a set of memory locations within a memory device. Except as explicitly described herein, such a memory device may be a read-only memory, random access memory, volatile memory, non-volatile memory, static memory, dynamic memory, flash memory, cache memory, and/or any device that stores digital information, and the memory device may be in a form a solid-state memory, a hard drive memory, cloud memory, thumb drive, server memory, computing device memory, and/or other physical medium for storing digital information. A computer readable memory/storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. A method for execution by one or more processing modules of a dispersed storage network (DSN), the DSN including a plurality of storage units, the method comprises:
receiving a data object for storage in the DSN;
determining metadata associated with the data object;
encoding a segment of the data object into n encoded data slices;
based at least in part on the metadata, selecting a first storage mode of a plurality of storage modes for storage of at least one of the encoded data slices, wherein the first storage mode includes selection of at least one storage unit utilizing solid-state memory for storage of encoded data; and
facilitating storage of the at least one of the encoded data slices in the at least one storage unit utilizing solid-state memory.

2. The method of claim 1, wherein determining to store the at least one of the encoded data slices in accordance with the first storage mode includes determining to store n of the encoded data slices in accordance with the first storage mode.

3. The method of claim 1, wherein determining to store the at least one of the encoded data slices in accordance with the first storage mode includes determining to store k of the encoded data slices in accordance with the first storage mode, the method further comprises:
determining to store n-k of the encoded data slices in accordance with a second storage mode of the plurality of storage modes, wherein the second storage mode includes selection of at least one storage unit utilizing a memory type other than solid-state memory for storage of encoded data, and wherein k is equal to or greater than a decode threshold number of the encoded data slices required to recover the segment of the data object; and
facilitating storage of the n-k encoded data slices in the at least one storage unit utilizing a memory type other than solid-state memory.

4. The method of claim 1, wherein the metadata comprises at least one of:
a data type;
a data size;
a data priority;
a data security index;
a reliability indicator;
a performance indicator;
an estimated storage time;
an estimated time between retrievals; or
a storage requirement.

5. The method of claim 1, wherein the first storage mode includes a time phase indicator that specifies a first time phase and a second time phase, the first time phase corresponding to a time period from an initial storage of the at least one of the encoded data slices in the at least one storage unit utilizing solid-state memory, the second time phase corresponding to a time period after the first time phase expires, the method further comprises:
facilitating storage of the at least one of the encoded data slices in accordance with a second storage mode of the plurality of storage modes during the second time phase, wherein the second storage mode includes selection of at least one storage unit utilizing a memory type other than solid-state memory for storage of encoded data.

6. The method of claim 5, wherein the data object is encoded in accordance with a first error coding dispersal function to produce encoded data slices for storage during the first time phase, and wherein the data object is encoded in accordance with a second error coding dispersal function to produce encoded data slices for storage during the second time phase.

7. The method of claim 1, wherein facilitating storage of the at least one of the encoded data slices in the at least one storage unit utilizing solid-state memory includes:
determining a virtual DSN address to physical location mapping for the at least one storage unit; and
sending the at least one of the encoded data slices to the at least one storage unit in accordance with the physical location mapping.

8. The method of claim 1 further comprises:
determining to reassess the selection of the first storage mode based on at least one of:
an elapsed period of time since the first storage mode was established;
a determination that the encoded data slices have not been access within a specified time period;
a command;
a request; or
a determination that the at least one storage unit has reached a memory utilization threshold.

9. The method of claim 1 further comprises:
determining to reassess the selection of the first storage mode based on at least one of:
an update to the metadata associated with the data object;
a change in memory device characteristics of one or more of the plurality of storage units; or
a change in available memory devices of one or more of the plurality of storage units.

10. The method of claim 1, wherein the at least one storage unit utilizes only solid-state memory for storage of encoded data slices.

11. A computing device for use in a dispersed storage network (DSN), the DSN including a plurality of storage units, the computing device comprises:
a network interface;
a local memory; and
a processing module operably coupled to the network interface and the local memory, wherein the processing module is configured to:
receive, via the network interface, a data object for storage in the DSN;
determine metadata associated with the data object;
encode a segment of the data object into n encoded data slices;
based at least in part on the metadata, select a first storage mode of a plurality of storage modes for storage of at least one of the encoded data slices, wherein the first storage mode includes selection of at least one storage unit utilizing solid-state memory for storage of encoded data; and
facilitate, via the network interface, storage of the at least one of the encoded data slices in the at least one storage unit utilizing solid-state memory.

12. The computing device of claim 11, wherein determining to store the at least one of the encoded data slices in accordance with the first storage mode includes determining to store n of the encoded data slices in accordance with the first storage mode.

13. The computing device of claim 11, wherein determining to store the at least one of the encoded data slices in accordance with the first storage mode includes determining to store k of the encoded data slices in accordance with the first storage mode, and wherein the processing module is further configured to:
determine to store n-k of the encoded data slices in accordance with a second storage mode of the plurality of storage modes, wherein the second storage mode includes selection of at least one storage unit utilizing a memory type other than solid-state memory for storage of encoded data, and wherein k is equal to or greater than a decode threshold number of the encoded data slices required to recover the segment of the data object; and
facilitate, via the network interface, storage of the n-k encoded data slices in the at least one storage unit utilizing a memory type other than solid-state memory.

14. The computing device of claim 11, wherein the metadata comprises at least one of:
a data type;
a data size;
a data priority;
a data security index;
a reliability indicator;
a performance indicator;
an estimated storage time;
an estimated time between retrievals; or
a storage requirement.

15. The computing device of claim 11, wherein the first storage mode includes a time phase indicator that specifies a first time phase and a second time phase, the first time phase corresponding to a time period from an initial storage of the at least one of the encoded data slices in the at least one storage unit utilizing solid-state memory, the second time phase corresponding to a time period after the first time phase expires, wherein the processing module is further configured to:
facilitate, via the network interface, storage of the at least one of the encoded data slices in accordance with a second storage mode of the plurality of storage modes during the second time phase, wherein the second storage mode includes selection of at least one storage unit utilizing a memory type other than solid-state memory for storage of encoded data.

16. The computing device of claim 11, wherein the processing module is further configured to:
maintain, in the local memory, a virtual DSN address to physical location mapping table including information used to facilitate the storage of the at least one of the encoded data slices in the at least one storage unit utilizing solid-state memory.

17. The computing device of claim 11, wherein the processing module is further configured to:
reassess the selection of the first storage mode based on at least one of:
an elapsed period of time since the first storage mode was established;
a determination that the encoded data slices have not been access within a specified time period;
a command;
a request; or
a determination that the at least one storage unit has reached a memory utilization threshold.

18. The computing device of claim 11, wherein the processing module is further configured to:
reassess the selection of the first storage mode based on at least one of:
an update to the metadata associated with the data object;
a change in memory device characteristics of one or more of the plurality of storage units; or
a change in available memory devices of one or more of the plurality of storage units.

19. A storage unit for use in a dispersed storage network (DSN), the storage unit comprises:
a network interface;
at least one solid-state memory device and at least one other type of memory device;
a processing module operably coupled to the network interface, the solid-state memory device and the at least one other type of memory device, wherein the processing module is configured to:
receive, via the network interface, an encoded data slice of a set of related encoded data slices for storage in the storage unit;
receive, via the network interface, metadata associated with the encoded data slice;
determine availability of the at least one solid-state memory device and at least one other type of memory device; and
based on the metadata and the availability of the at least one solid-state memory device and at least one other type of memory device, determining to store the encoded data slice in at least one of the solid-state memory device and the at least one other type of memory device.

20. The storage unit of claim 19, wherein determining the availability of the at least one solid-state memory device and at least one other type of memory device is based, at least in part, on operational data stored in the storage unit.
